(19) United States
(12) Patent Application Publication
(10) Pub. No.: US 2026/0190695 A1
(43) Pub. Date: Jul. 2, 2026

(54) DISPLAY DEVICE

(71) Applicant: LG Display Co., Ltd., Seoul (KR)

(72) Inventors: Juwon JEON, Seoul (KR); Minjoo KIM, Seoul (KR); Dongil CHU, Gimpo-si (KR); Sukhyun KANG, Goyang-si (KR)

(73) Assignee: LG Display Co., Ltd., Seoul (KR)

(21) Appl. No.: 19/322,152

(22) Filed: Sep. 8, 2025

(30) Foreign Application Priority Data
Dec. 31, 2024 (KR) 10-2024-0202524

(51) Int. Cl. H10K 59/131

(52) U.S. Cl. CPC H10K 59/131

(57) ABSTRACT

A display device includes a substrate including a display area and a non-display area outside the display area such that a link area and a bendable area included in the non-display area; a plurality of signal link lines on the link area; and a plurality of connection lines respectively connected to the plurality of signal link lines and extending from the link area to the bendable area to be on the bendable area. Each of the connection lines includes an upper pattern, a plurality of lower patterns vertically spaced apart from the upper pattern, and a plurality of contact electrodes between the plurality of lower patterns and the upper pattern to connect the upper pattern to the plurality of lower patterns.

### CROSS REFERENCE TO RELATED APPLICATION

The present application claims priority to Korean Patent Application No. 10-2024-0202524, filed on Dec. 31, 2024, the entire contents of which is incorporated herein for all purposes by this reference.

### BACKGROUND

### Technical Field

The present disclosure relates to a display device.

### Discussion of the Related Art

A display device can be applied to various electronic devices, such as a TV, a smartphone, a laptop computer, and a tablet. To this end, research is being conducted to develop a thin, light weight, and low power consuming display device. Examples of the display device include a LCD (Liquid Crystal Display) device, a FED (Field Emission Display) device, and an OLED (Organic Light-emitting Display) device.

A bezel area of the display device may be visually recognized by a user and, thus, may be a factor that degrades a sense of immersion in an image emitted from the display area. Accordingly, recently, there is an increasing demand for a display device implementing a narrow bezel in which a bezel area in which a screen of the display device is not displayed is reduced or a zero bezel that substantially has an effect of not having a bezel area.

### SUMMARY

As a flexible substrate made of a flexible material is applied to the display device, the display panel may include a bendable area that is bent to hide a pad area under the display area. This may reduce a size of the bezel area of the display device visually recognized by the user.

The bendable area may include a plurality of connection lines to transmit various signals to the pixels of the display area, and the plurality of connection lines may be connected to signal lines in a link area adjacent to the display area.

However, cracks may occur in the lines disposed in the bendable area due to an external impact or the like, or cracks may occur in the organic insulating layer disposed in the bendable area due to an external impact or the like. In addition, moisture may penetrate through the generated crack. When the moisture penetrates, there may be a problem in that the connection line in the bendable area may corrode.

When the signal lines are corroded, a defect rate of the display device in which the pixels in the display area are not turned on may increase. When the defect rate of the display device increases, the production energy required for the production of the display device increases so that increased greenhouse gas emission may occur.

Accordingly, embodiments of the present disclosure are directed to a display device that substantially obviates one or more of the problems due to limitations and disadvantages of the related art.

An aspect of the present disclosure is to provide a display device capable of preventing or reducing cracks in or damage to the line disposed in the bendable area from occurring due to the stress applied thereto.

Another aspect of the present disclosure is to provide a display device capable of preventing or avoiding a crack from occurring in a line a bendable area, thereby preventing or reducing moisture from penetrating into the line through the crack.

Another aspect of the present disclosure is to provide a display device including a robust structure in which a line disposed in a bendable area may maintain stable and reliable performance even under external environmental changes or conditions.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a display area and a non-display area, the non-display area being outside the display area, wherein a link area and a bendable area included in the non-display area; a plurality of signal link lines on the link area; and a plurality of connection lines respectively connected to the plurality of signal link lines and extending from the link area to the bendable area to be on the bendable area, wherein each of the connection lines includes: an upper pattern; a plurality of lower patterns vertically spaced apart from the upper pattern; and a plurality of contact electrodes between the plurality of lower patterns and the upper pattern to connect the upper pattern to the plurality of lower patterns.

In another aspect, a display device, comprises a substrate including a display area and a non-display area outside the display area, the non-display area including a link area, a pad area, and a bendable area between the link area and the pad area; a plurality of signal link lines on the link area; a plurality of signal lines on the pad area; and a plurality of connection lines respectively connected to the plurality of signal link lines in the link area and respectively connect to the plurality of signal lines in the pad area, the plurality of connection lines extending from the link area to the pad area via the bendable area, wherein each of the connection lines includes: a first upper pattern over the link area, a second upper pattern over the pad area, a plurality of lower patterns below and spaced apart from the first and second upper patterns, a plurality of first contact electrodes connecting respective ones of the plurality of the lower patterns with the first upper pattern, and a plurality of second contact electrodes connecting respective ones of the plurality of the lower patterns with the first upper pattern.

In the display device according to an embodiment of the present disclosure, the connection line extending from the link area to be disposed in the bendable area may be divided into the upper pattern and the plurality of lower patterns, thereby reducing the magnitude of tensile stress applied to the connection line during the bending operation of the display panel.

Accordingly, a display device according to embodiments of the present disclosure may prevent or avoid cracks or damage due to stress from occurring in the connection line disposed in the bendable area.

In addition, a display device according to embodiments of the present disclosure has an effect of reducing the stress magnitude by increasing the contact area between the connection line and the underlying planarization layer.

Accordingly, a display device according to embodiments of the present disclosure has an effect of reducing the emission of greenhouse gas by reducing the defect rate of the display device to reduce the production energy required for the production of the display device.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is an exploded perspective view of a display device according to embodiments of the present disclosure.

FIG. 2 is a plan view of a display panel according to embodiments of the present disclosure.

FIG. 3 is a cross-sectional view taken along a line I-I′ of FIG. 2.

FIG. 4 is an enlarged view of an area II of FIG. 2.

FIG. 5 is a cross-sectional view taken along a line III-III′ of FIG. 4.

FIG. 6 is an enlarged view of an area IV of FIG. 2.

FIG. 7 is a cross-sectional view taken along a line V-V′ of FIG. 6.

FIGS. 8 to 10 are diagrams illustrating a bendable area according to an embodiment of the disclosure.

FIGS. 11 to 15 are diagrams illustrating a bendable area according to another embodiment of the present disclosure.

FIG. 16 is a diagram illustrating a connection line according to an embodiment of the present disclosure.

FIGS. 17 to 19 are respective diagrams illustrating connection lines according to still another embodiment of the present disclosure.

FIGS. 20 to 24 are diagrams illustrating a method for manufacturing a connection line according to another embodiment of the present disclosure.

FIGS. 25 and 26 are diagrams illustrating a method for manufacturing a connection line according to still another embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expressions, such as “at least one of” when preceding a list of elements, may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to” or “coupled to” another element or layer, it may be directly connected to, or coupled to the other element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events, such as “after,” “subsequent to,” “before,” etc., another event may occur therebetween unless “directly after,” “directly subsequent,” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term “or” means “inclusive or” rather than “exclusive or.” Unless otherwise stated or clear from the context, the expression that ‘x uses a or b’ means one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase “immediately transferred” or “directly transferred” is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure may work functionally.

Hereinafter, a display device according to an embodiment of the present disclosure will be described with reference to the drawings.

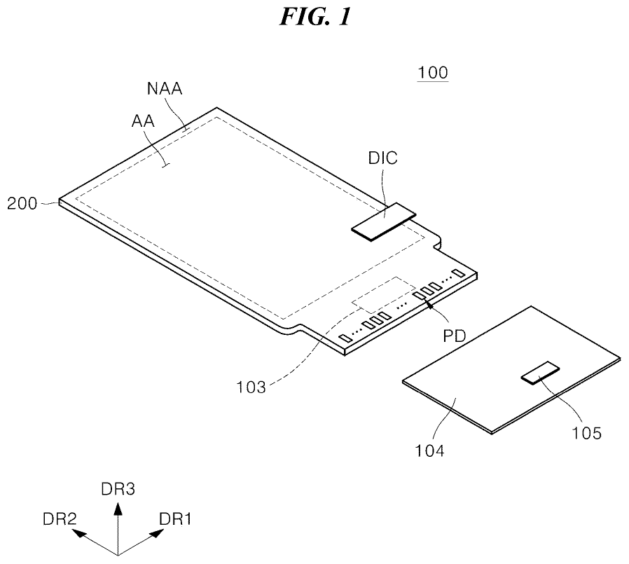

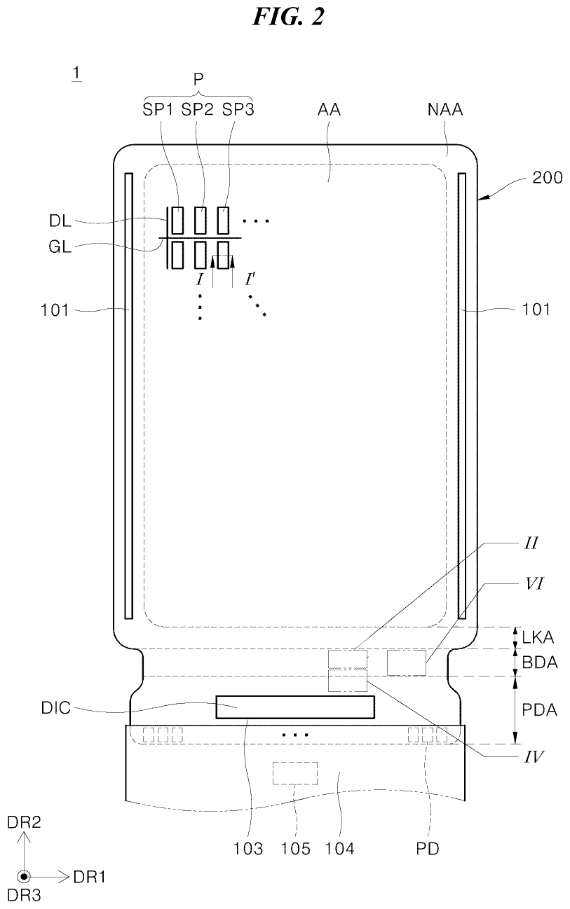

FIG. 1 is an exploded perspective view of a display device according to embodiments of the present disclosure. FIG. 2 is a plan view of a display panel according to embodiments of the present disclosure;

As shown in FIGS. 1 and 2, a display device 100 may include a display panel 200, a gate driver 101, a data driver DIC, a printed circuit board 104, and a control circuit chip 105.

The display panel 200 may include a display area AA and a non-display area NAA. The display area AA may be an area in which an image is displayed. The non-display area NAA may be an area in which no image is displayed. The non-display area NAA may be located in a peripheral area (or an edge area) of the display panel 100. However, embodiments of the present disclosure are not limited thereto. For example, an area other than a light emission area in which light is emitted to the outside in the display area AA may be referred to as the non-display area NAA. A bezel area of the display device 100 may be defined by the non-display area NAA. The bezel area may surround the display area AA. A link area LKA, a bendable area BDA, and a pad area PDA may be disposed in a lower end area of the non-display area NAA.

A plurality of pixels P may be disposed in the display area AA. One pixel P may include a plurality of sub-pixels SP1, SP2, and SP3. A light-emitting element and circuit elements for driving the light-emitting element may be disposed in each of the sub-pixels SP1, SP2, and SP3. For example, the circuit elements may include transistors and a capacitor. An image may be displayed in the display area AA through the plurality of sub-pixels SP1, SP2, and SP3. The plurality of sub-pixels SP1, SP2, and SP3 may be arranged in the display area AA that is to be spaced apart from each other in a first direction DR1 and a second direction DR2 intersecting the first direction DR1. However, the present disclosure is not limited thereto.

The plurality of sub-pixels SP1, SP2, and SP3 may include a first sub-pixel SP1, a second sub-pixel SP2, and a third sub-pixel SP3 that emit light of different colors. For example, the first sub-pixel SP1 may emit red light, the second sub-pixel SP2 may emit green light, and the third sub-pixel SP3 may emit blue light. In an embodiment of the present disclosure, only three sub-pixels are illustrated. However, the present disclosure is not limited thereto. For example, one pixel P may include an additional sub-pixel in addition to the three sub-pixels.

The display area AA includes a plurality of data lines DL and a plurality of gate lines GL disposed to intersect each other. For example, one sub-pixel may be defined in an intersection area in which one data line DL and one gate line GL intersect each other. The data line DL may transmit the data signal generated by the data driver DIC to the sub-pixel, and the gate line GL may transmit the gate signal generated by the gate driver 101 to the sub-pixel. The gate driver 101 may be disposed in the non-display area NAA and located on each of the left and right sides of the display area AA. The data driver DIC may be manufactured as a driving circuit chip and mounted on a data driver area 103. The gate lines GL may extend in the first direction X of the display panel 200, and the data lines DL may intersect the gate lines GL and extend in the second direction Y of the display panel 200.

Various lines and circuits for driving the plurality of subpixels SP1, SP2, and SP3 of the display area AA may be disposed in the non-display area NAA. For example, the driving circuits including a gate driving circuit and a data driving circuit may be disposed in the non-display area NAA. Several drivers for driving the display area AA may be disposed in the non-display area NAA. For example, the drivers may include the gate driver 101 and the data driver DIC. However, embodiments of the present disclosure are not limited thereto.

The non-display area NAA may include the link area LKA, the bendable area BDA, and the pad area PDA disposed in the lower side area of the display panel 200. The link area LKA may be disposed between the display area AA and the pad area PDA, and the bendable area BDA may be disposed between the link area LKA and the pad area PDA.

A plurality of link lines may be disposed in the link area LKA. The link line may include data link lines for electrically connecting the data lines DL of the display area AA and the data driver DIC to each other, touch link lines for electrically connecting the touch lines and the data driver DIC to each other, or signal link lines for connecting several signal lines or power lines to the control circuit chip 105 on the printed circuit board 104. The control circuit chip 105 on the printed circuit board 104 may control the data driver DIC and the gate driver 101.

A plurality of pads PD electrically connected to the printed circuit board 104 may be disposed in the pad area PDA. The link lines extending from the display area AA across the link area LKA to the printed circuit board 104 may be disposed in the bendable area BDA. The bendable area BDA of the display panel 200 may be bent so that the printed circuit board 104 may be disposed on a rear surface of the display area AA of the display panel 200. As the bendable area BDA of the display panel 200 is bent, the pad area PDA of the non-display area NAA may be located under the display area AA. Accordingly, a size of a lower bezel area of the display device 1 as recognized from a viewer in front of the display device 1 may be reduced.

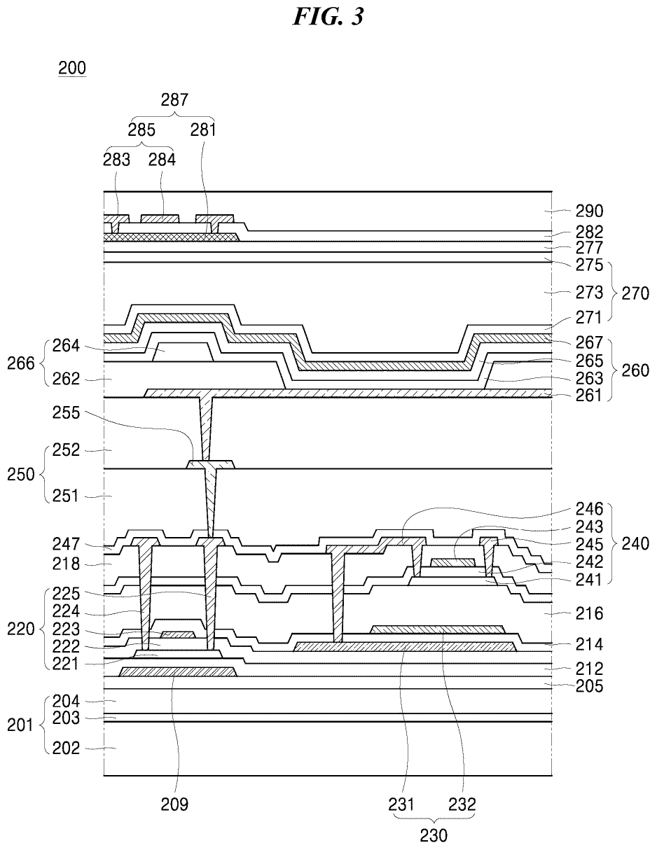

FIG. 3 is a cross-sectional view taken along a line I-I′ of FIG. 2. FIG. 3 schematically illustrates one sub-pixel of a display device. In the present disclosure, for convenience of description, an example of a configuration of one sub-pixel is described. However, the present disclosure is not limited thereto.

As illustrated in FIG. 3, the display panel 200 may include a pixel driving circuit including a plurality of transistors 220 and 240 disposed on a substrate 201, a light-emitting element 260, and a touch sensor 287. One sub-pixel may include a light-emitting element 260 and a pixel driving circuit that applies a driving current to the light-emitting element 260. The pixel driving circuit is disposed on the substrate 201, and the light-emitting element 260 is disposed on the pixel driving circuit. The pixel driving circuit may include a plurality of transistors 220 and 240 and a storage capacitor 230. In an example, the plurality of transistors 220 and 240 may include a first transistor 220 and a second transistor 240.

The substrate 201 may be a flexible plastic substrate. When the substrate 201 is formed as a plastic film, the substrate 201 may include multiple layers made of an insulating material. For example, the substrate 201 may include a first base layer 202 and a second base layer 204 spaced apart from each other in a vertical direction, and a support layer 203 disposed therebetween. Each of the first base layer 202 and the second base layer 204 may include plastic of a flexible material. For example, each of the first base layer 202 and the second base layer 204 may may include polyimide (PI). The support layer 203 may be made of a material having a relatively higher rigidity than that of each of the first base layer 202 and the second base layer 204 to reinforce the rigidity of the substrate 201.

A first buffer layer 205 may be disposed on the substrate 201. The first buffer layer 205 may cover a surface of the substrate 201. For example, the first buffer layer 205 may entirely cover the surface of the substrate 201. For example, the first buffer layer 205 may extend to the link area LA. The first buffer layer 205 may reduce or prevent penetration of moisture, oxygen, or impurities through the substrate 201. The first buffer layer 205 may be embodied as a single layer or a multilayer made of an inorganic insulating material, such as silicon oxide (SiOx) or silicon nitride (SiNx).

A light-shielding layer 209 may be disposed on the first buffer layer 205. The light-shielding layer 209 may prevent, or at least reduce, external light from being incident on the transistor TR. To this end, the light-shielding layer 209 may include an opaque metal material. A second buffer layer 212 may be disposed on the light-shielding layer 209. The second buffer layer 212 may protect the transistor TR from moisture, oxygen, or impurities. The second buffer layer 212 may be embodied as a single layer or a multilayer made of an inorganic insulating material, such as silicon oxide (SiOx) or silicon nitride (SiNx). However, embodiments of the present disclosure are not limited thereto. The second buffer layer 212 may entirely cover the surface of the substrate 201. For example, the second buffer layer 212 may extend to the link area LKA.

The first transistor 220 may be disposed on the second buffer layer 212. The first transistor 220 may include a first semiconductor layer 221, a first gate insulating layer 222, a first gate electrode 223, a first source electrode 224, and a first drain electrode 225. In an example, the first transistor 220 may be a driving transistor electrically connected to the light-emitting element 260.

The first semiconductor layer 221 may include a channel area and source/drain areas. An area of the first semiconductor layer 221 overlapping the first gate electrode 223 in the vertical direction may be a channel area. The source/drain areas may be disposed on both opposing sides of the channel area, respectively. The first semiconductor layer 221 may include one of a polysilicon semiconductor layer and a low-temperature polysilicon semiconductor layer, or a combination thereof. The first semiconductor layer 221 may be disposed to overlap the light-shielding layer 209 in the vertical direction. The light-shielding layer 209 may prevent, or at least reduce, external light from being incident on the first semiconductor layer 221.

The first gate insulating layer 222 may be disposed between the first semiconductor layer 221 and the first gate electrode 223. The first gate insulating layer 222 may extend outwardly while covering the first semiconductor layer 221. The first gate insulating layer 222 may be embodied as a single layer or a stack of a plurality of layers made of an inorganic insulating material, such as silicon oxide (SiOx) or silicon nitride (SiNx).

The first gate electrode 223 may be disposed on the first gate insulating layer 222. A first interlayer insulating layer 214 may be disposed on the first gate electrode 223. The first interlayer insulating layer 214 may be embodied as a single layer or a stack of multiple layers made of an inorganic insulating material, such as silicon oxide (SiOx) or silicon nitride (SiNx). In an example, the first interlayer insulating layer 214 may extend to the link area LKA. The first source electrode 224 and the first drain electrode 225 may be electrically connected to the first semiconductor layer 221.

The storage capacitor 230 may include a first storage electrode 231 and a second storage electrode 232. For example, the first storage electrode 231 and the first gate electrode 223 may be formed on the same layer 222. For example, the first storage electrode 231 may be disposed on the first gate insulating layer 222 and at a position horizontally spaced apart from the first gate electrode 223. The first storage electrode 231 may be made of the same material as that of the first gate electrode 223. The second storage electrode 232 may be disposed on the first interlayer insulating layer 214 to overlap the first storage electrode 231 in the vertical direction. Each of the first storage electrode 231 and the second storage electrode 232 may be embodied as a single layer or as a stack of multiple layers made of one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

A second interlayer insulating layer 216 may be disposed on the second storage electrode 232. The second interlayer insulating layer 216 may be embodied as a single layer or a stack of multiple layers made of an inorganic insulating material, such as silicon oxide (SiOx) or silicon nitride (SiNx).

The second transistor 240 may be disposed on the second interlayer insulating layer 216 to be spaced apart from the first transistor 220. The second transistor 240 may be electrically connected to the first transistor 220. For example, the second transistor 240 may include a second semiconductor layer 241, a second gate insulating layer 242, a second gate electrode 243, a second source electrode 245, and a second drain electrode 246. In an example, the second transistor 240 may be a switching transistor.

The second semiconductor layer 241 may include a channel area and source/drain areas. A area of the second semiconductor layer 241 overlapping the second gate electrode 243 in the vertical direction may be a channel area. The source/drain areas may be disposed on both opposing sides of the channel area, respectively. The second semiconductor layer 241 may include an oxide semiconductor layer. In an example, the second semiconductor layer 241 may be disposed to overlap the storage capacitor 230 in the vertical direction. Accordingly, the storage capacitor 230 may prevent, or at least reduce, the external light from the outside out of the substrate 201 from being incident on the second semiconductor layer 241. Accordingly, this may prevent, or at least reduce, the characteristics of the second transistor 240 from being changed by the external light.

The second gate insulating layer 242 may be disposed between the second semiconductor layer 241 and the second gate electrode 243. The second gate insulating layer 242 may extend outwardly while covering the second semiconductor layer 241. For example, the second gate insulating layer 242 may extend to the link area LKA. The second gate insulating layer 242 may be embodied as a single layer or a stack of a plurality of layers made of an inorganic insulating material, such as silicon oxide (SiOx) or silicon nitride (SiNx).

Each of the first gate electrode 223 or the second gate electrode 243 may be embodied as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, an example of the material is not limited thereto.

A third interlayer insulating layer 218 may be disposed on the second gate electrode 243. The third interlayer insulating layer 218 may include an inorganic insulating material. For example, the third interlayer insulating layer 218 may include an inorganic insulating material, such as silicon oxide (Six), silicon nitride (SiNx), or silicon oxynitride (SiON), and may be embodied as a single layer or a stack of multiple layers.

The first source electrode 224, the first drain electrode 225, the second source electrode 245, and the second drain electrode 246 may be disposed on the third interlayer insulating layer 218. The first source electrode 224 and the first drain electrode 225 may extend through the third interlayer insulating layer 218, the second gate insulating layer 242, the second interlayer insulating layer 216, the first interlayer insulating layer 214, and the first gate insulating layer 222 to be in direct contact with and be electrically connected to the source/drain areas of the first semiconductor layer 221, respectively.

The second source electrode 245 and the second drain electrode 246 may extend through the third interlayer insulating layer 218 and the second gate insulating layer 242 to directly contact and be electrically connected to the source/drain areas of the second semiconductor layer 241, respectively. The second drain electrode 246 of the second transistor 240 may be electrically connected to the storage capacitor 230. For example, a portion of the second drain electrode 246 may extend through the third interlayer insulating layer 218, the second gate insulating layer 242, the second interlayer insulating layer 216, and the first interlayer insulating layer 214 to be in direct contact with and be electrically connected to the first storage electrode 231 of the storage capacitor 230.

Each of the first source electrode 224, the first drain electrode 225, the second source electrode 245, or the second drain electrode 246 may be embodied as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto. In an example, each of the first source electrode 224 or the second drain electrode 225 may have a stack structure of titanium layer/aluminum layer/titanium layer (Ti/Al/Ti).

A passivation layer 247 may be disposed on the first source electrode 224, the first drain electrode 225, the second source electrode 245, or the second drain electrode 246. The passivation layer 247 may include an inorganic insulating material, such as silicon oxide, silicon nitride, and silicon oxynitride, and may be embodied as a single layer or a stack of multiple layers. The passivation layer 247 may protect the pixel driving circuit disposed thereunder.

A planarization layer 250 may be disposed on the passivation layer 247. The planarization layer 250 may planarize a step caused due to the pixel driving circuit thereunder. The planarization layer 250 may include a multilayer structure. For example, the planarization layer 250 may include a stack of a first planarization layer 251 and a second planarization layer 252. For example, the planarization layer 250 may include an organic insulating material, such as polyimide or acrylic resin. In an example, each of the first planarization layer 251 and the second planarization layer 252 may extend to the link area LKA.

A pixel contact electrode 255 may be disposed on the first planarization layer 251. The pixel contact electrode 255 may extend thorough the first planarization layer 251 and the passivation layer 247 to directly contact the first drain electrode 225 of the first transistor 220.

The light-emitting element 260 may be formed on the planarization layer 250. For example, the light-emitting element 260 may be disposed on the second planarization layer 252. The light-emitting element 260 may include a first electrode 261, a light-emitting layer 263, a second electrode 265, and a capping layer 267.

The light-emitting element 260 may be electrically connected to the pixel driving circuit via the first electrode 261. For example, the first electrode 261 may extend through the second planarization layer 252 to directly contact the pixel contact electrode 255. Accordingly, the first electrode 261 may be electrically connected to the first transistor 220 via the pixel contact electrode 255. The pixel contact electrode 255 may include a conductive material. For example, the pixel contact electrode 255 may include a metal material, such as aluminum (Al), chromium (Cr), copper (Cu), titanium (Ti), molybdenum (Mo), and tungsten (W). In an example, the pixel contact electrode 255 may have a multilayer structure of titanium layer/aluminum layer/titanium layer (Ti/Al/Ti).

The first electrode 261 may include a transparent conductive layer. For example, the first electrode 261 may include ITO (Indium Tin Oxide) or IZO (Indium Zinc Oxide). Alternatively, the first electrode 261 may have a single-layer or a multi-layer structure including a reflective metal film made of one of silver (Ag), aluminum (Al), gold (Au), nickel (Ni), and chromium (Cr) or an alloy thereof. The first electrode 261 may also be referred to as a pixel electrode or an anode electrode.

A bank 262 may be disposed on the first electrode 261. The bank 262 may be disposed to cover an edge of the first electrode 261. A portion of the bank 262 may extend to the second planarization layer 252. A portion of an upper surface of the first electrode 261 not covered with the bank 262 to be exposed may be the light emission area EA. The bank 262 may be made of an organic insulating material. The bank 262 may include, for example, photosensitive polyimide, photoacryl, or benzocyclobutene (BCB).

A spacer 264 may be further disposed on the bank 262. The spacer 264 may be disposed to prevent, or at least reduce, damage to the bank 262 and the first electrode 261 during the process. The spacer 264 may be made of the same material as that of the bank 262. The bank 262 and the spacer 264 may overlap each other in the vertical direction to constitute a barrier layer 266. In an example, the barrier layer 266 may extend to the non-display area NAA. For example, the barrier layer 266 may extend to the bendable area BDA.

The light-emitting layer 263 may be disposed on the first electrode 261. The light-emitting layer 263 may include a hole transport layer HTL, an organic light-emitting layer EML, an electron transport layer ETL, a hole blocking layer HBL, a hole injecting layer HIL, an electron blocking layer EBL, and an electron injecting layer EIL. The light light-emitting layer 263 may have a multi-layer structure.

The second electrode 265 may be disposed on the light-emitting layer 263. The second electrode 265 may be commonly connected to the light-emitting layer 263 formed in all pixels. Therefore, the second electrode 265 may also be referred to as a cathode electrode or a common electrode. The second electrode 265 may include a transflective conductive material. For example, the cathode electrode may be made of a metal material, such as magnesium (Mg), silver (Ag), or an alloy (Ag—Mg) of silver (Ag) and magnesium (Mg). In an example, the second electrode 265 may include a transparent conductive layer, such as indium-tin-oxide (ITO) or indium-zinc-oxide (IZO).

The capping layer 267 may be disposed on the second electrode 265. The capping layer 267 may prevent, or at least reduce, light generated from the light-emitting layer 263 from being lost, thereby improving light extraction efficiency.

The encapsulation stack 270 may be disposed on the light-emitting element 260. The encapsulation stack 270 may protect the light-emitting element 260 from external oxygen or moisture. The encapsulation stack 270 may extend to the non-display area NAA outside the display area AA while covering the display area AA.

The encapsulation stack 270 may include a multilayer structure in which a first encapsulation layer 271, a second encapsulation layer 273, and a third encapsulation layer 275 are stacked. The second encapsulation layer 273 may be disposed between the first encapsulation layer 271 and the third encapsulation layer 275.

The first encapsulation layer 271 may be disposed on the capping layer 267. The second encapsulation layer 273 may be disposed on the first encapsulation layer 271. The second encapsulation layer 273 may cover the first encapsulation layer 271 and may have a sufficient thickness to have a flat upper surface. The second encapsulation layer 273 may prevent, or at least reduce, foreign substances from penetrating into the light-emitting element 260. The third encapsulation layer 275 may be disposed on the second encapsulation layer 273.

Each of the first encapsulation layer 271 and the third encapsulation layer 275 may include an inorganic insulating material, and the second encapsulation layer 273 may include an organic insulating material. For example, each of the first encapsulation layer 271 and the third encapsulation layer 275 may include at least one of silicon nitride (SiNx), silicon oxide (SiOx), or silicon oxynitride (SiON). The second encapsulation layer 273 may include at least one of epoxy, polyimide, polyethylene, and acrylate.

A touch area may be disposed on the encapsulation stack 270. The touch area may include a touch buffer layer 277, a touch sensor 287, a touch interlayer insulating layer 282, and a touch protective layer 290.

The touch buffer layer 277 may be disposed on the third encapsulation layer 275. The touch buffer layer 277 may reduce stress between the encapsulation stack 270 and the layer of the touch sensor 287 to prevent, or at least avoid, the encapsulation stack 270 and the light-emitting element 260 from being damaged. The touch buffer layer 277 may include an inorganic insulating material. For example, the touch buffer layer 277 may include silicon nitride (SiNx).

The touch sensor 287 may include a plurality of touch electrodes 285 and a bridge electrode 281. The plurality of touch electrodes 285 and the bridge electrode 281 may be disposed in different layers. For example, the bridge electrode 281 may be disposed on the touch buffer layer 277. The plurality of touch electrodes 287 may be disposed on the touch interlayer insulating layer 282. The plurality of touch electrodes 287 may include a first touch electrode 283 and a second touch electrode 284. The bridge electrode 281 may electrically connect adjacent first touch electrodes 283 to each other. To this end, the first touch electrode 283 may extend through the touch interlayer insulating layer 282 to be connected to the bridge electrode 281. The touch interlayer insulating layer 282 may include an inorganic insulating material. For example, the touch interlayer insulating layer 282 may include silicon nitride (SiNx).

The first touch electrode 283, the second touch electrode 284, or the bridge electrode 281 may include a conductive material. The first touch electrode 283, the second touch electrode 284, or the bridge electrode 281 may include a single layer or a stack of multiple layers made of one of molybdenum (Mo), aluminum (Al), chromium (Cr), gold (Au), titanium (Ti), nickel (Ni), neodymium (Nd), and copper (Cu) or an alloy thereof. For example, each of the first touch electrode 283, the second touch electrode 284, or the bridge electrode 281 may have a stacked structure of titanium layer/aluminum layer/titanium layer (Ti/Al/Ti).

The touch interlayer insulating layer 282 may extend toward the non-display area NAA. In one example, the touch interlayer insulating layer 282 may extend to the link area LKA.

The touch protective layer 290 may be disposed on the touch sensor 287. The touch protective layer 290 may prevent, or at least reduce, damage to the touch sensor 287 from external impact and moisture. The touch protective layer 290 may include an organic insulating material. For example, the touch protective layer 290 may be made of a photosensitive acrylic-based or polyimide-based organic material. The touch protective layer 290 may extend to the non-display area NAA. For example, the touch protective layer 290 may extend to cover the touch interlayer insulating layer 282 in the link area LKA.

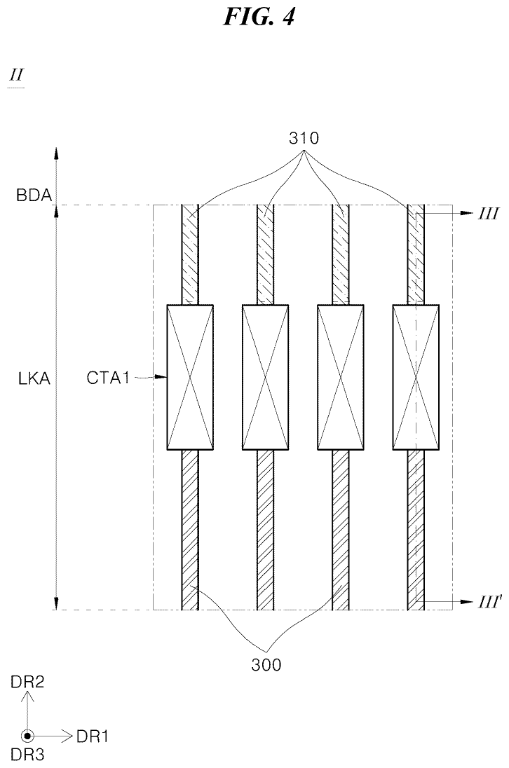

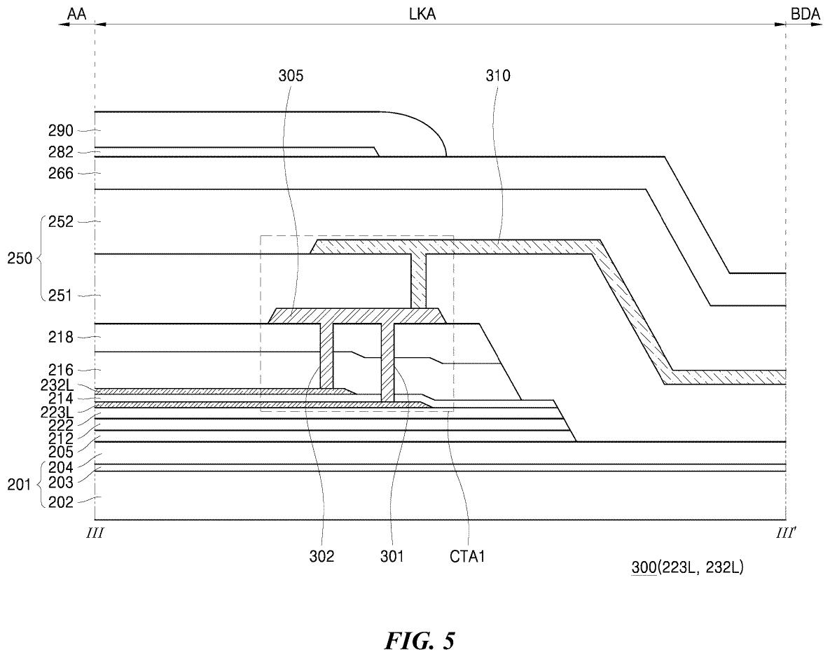

FIG. 4 is an enlarged view of an area II of FIG. 2. FIG. 5 is a cross-sectional view taken along a line III-III′ of FIG. 4; FIG. 4 illustrates a link area LKA of the display panel 200 and a boundary area between the link area LKA and the bendable area BDA. In FIGS. 4 and 5, the same components as those described in FIG. 3 may employ the same reference numerals.

With reference to FIGS. 4 and 5, a plurality of signal link lines 300 for transmitting signals or power to the display area AA may be disposed in the link area LKA. For example, the plurality of signal link lines 300 may be power lines for transmitting power for driving the pixels. For example, the plurality of signal link lines 300 may be connected to a low-potential power (VSS) line or a high-potential power (VDD) line. In another example, the plurality of signal link lines 300 may be data link lines. A plurality of connection lines 310 may be disposed in the link area LKA and extend toward the bendable area BDA. The link area LKA may include a first contact area CTA1.

Each of the plurality of signal link lines 300 may extend in the second direction DR2 and in the link area LKA. The connection line 310 may extend in the second direction DR2 and in the bendable area BDA. The second direction DR2 may be a column direction of the display panel 200. The plurality of signal link lines 300 may be respectively connected to the plurality of connection lines 310 in the first contact area CTA1 located in the link area LKA. Some of the plurality of connection lines 310 may be connected to the signal link line 300. In one example, the plurality of connection lines 310 may extend across the bendable area BDA to the pad area PDA. The signal link line 300 and the connection line 310 may be disposed at different layers.

As shown in FIG. 5, the first buffer layer 205, the second buffer layer 212, the first gate insulating layer 222, the first interlayer insulating layer 214, the second interlayer insulating layer 216, and the third interlayer insulating layer 218 may be disposed on the link area LKA of the substrate 201 to overlap each other in the vertical direction to form an insulating stack structure. Each of the first buffer layer 205, the second buffer layer 212, the first gate insulating layer 222, the first interlayer insulating layer 214, the second interlayer insulating layer 216, and the third interlayer insulating layer 218 may include an inorganic insulating material.

The first buffer layer 205, the second buffer layer 212, the first gate insulating layer 222, the first interlayer insulating layer 214, the second interlayer insulating layer 216, and the third interlayer insulating layer 218 may be made of an inorganic insulating material in which cracks are likely to occur. In this regard, an amount of the inorganic insulating material may be decreased on the link area LKA of the substrate 201 as the area extends toward the bendable area BDA. For example, the first planarization layer 251 and the second planarization layer 252 including an organic insulating material may be disposed on a portion of the link area adjacent to the bendable area BDA of the substrate 201 and on the bendable area BDA thereof. Because the first buffer layer 205, the second buffer layer 212, the first gate insulating layer 222, the first interlayer insulating layer 214, the second interlayer insulating layer 216, and the third interlayer insulating layer 218 of the substrate 201 are disposed in the link area LKA, a side end of the stack of these layers may define a boundary between the link area LKA and the bendable area BDA. For example, the side end of the stack of the first buffer layer 205 and the second buffer layer 212 disposed at the lowermost portion of the insulating stack structure may define a boundary between the bendable area BDA and the link area LKA. However, the present disclosure is not limited thereto.

The plurality of signal link lines 300 may be disposed on the link area LKA of the substrate 201. In an example, each of the plurality of signal link lines 300 may be disposed between respective layers of the insulating stack structure in the cross-sectional view. For example, the signal link line 300 may include a (1-1)th data link line 223L and a (1-2)th data link line 232L. In an example, the (1-1)th data link line 223L and the (1-2)th data link line 232L may be disposed at different layers and overlap each other in the vertical direction.

The (1-1)th data link line 223L may be disposed between the first gate insulating layer 222 and the first interlayer insulating layer 214 in the cross-sectional view. The (1-1)th data link line 223L may be made of the same material as that of the first gate electrode 223 and be formed in the same process as that thereof. The (1-2)th data link line 232L may be disposed on the first interlayer insulating layer 214 in the cross-sectional view. The (1-2)th data link line 232L may be made of the same material as that of and be formed in the same process as that of the second storage electrode 232.

A link contact electrode 305 may be disposed on the third interlayer insulating layer 218 and in the link area LKA. The link contact electrode 305 may be made of the same material as that of and be formed in the same process as that of the second source electrode 245 and the second drain electrode 246. The link contact electrode 305 may be electrically connected to the signal link line 300. For example, the link contact electrode 305 may be connected to the (1-1)th data link line 223L via a first via electrode 301 extending through the third interlayer insulating layer 218, the second interlayer insulating layer 216, and the first interlayer insulating layer 214. In addition, the link contact electrode 305 may be connected to the (1-2)th data link line 232L via a second via electrode 302 extending through the third interlayer insulating layer 218 and the second interlayer insulating layer 216. The first via electrode 301 and the second via electrode 302 may be integrally formed with the link contact electrode 305.

The first planarization layer 251 covering the link contact electrode 305 may be disposed on the third interlayer insulating layer 218. The first planarization layer 251 may be disposed on the link area LKA and the bendable area BDA of the substrate 201. For example, the first planarization layer 251 may be disposed on the bendable area BDA to be in direct contact with the substrate 201.

The connection line 310 may be disposed on the first planarization layer 251. The connection line 310 may be disposed on the link area LKA and the bendable area BDA. The connection line 310 may be made of the same material as that of and be formed in the same process as that of the pixel contact electrode 255 of the display area AA. In an example, the connection line 310 may have a multi-layered structure of titanium layer/aluminum layer/titanium layer (Ti/Al/Ti).

The connection line 310 may extend through the first planarization layer 251 to connected to the link contact electrode 305 in the first contact area CTA1. Accordingly, the connection line 310 may be electrically connected to the signal link line 300 via the link contact electrode 305. In an example, each link contact electrode 305 may be disposed in each first contact area CTA1, and neighboring link contact electrodes 305 may be electrically insulated from each other.

The second planarization layer 252 may be disposed on the connection line 310. The second planarization layer 252 may be disposed on the link area LKA and the bendable area BDA of the substrate 201 while covering the connection line 310. The second planarization layer 252 may planarize a step caused due to the underlying circuit elements.

A barrier layer 266 may be disposed on the second planarization layer 252 and in the link area LKA and the bendable area BDA. The barrier layer 266 may be made of the same material as that of and be formed in the same process as that of the bank 262 and the spacer 264.

The touch interlayer insulating layer 282 may be disposed on the barrier layer 266 in an area where the signal link line 300 is disposed. The touch interlayer insulating layer 282 may be covered with the touch protective layer 290. In an example, the touch protective layer 290 may be disposed on the link area LKA. However, the present disclosure is not limited thereto.

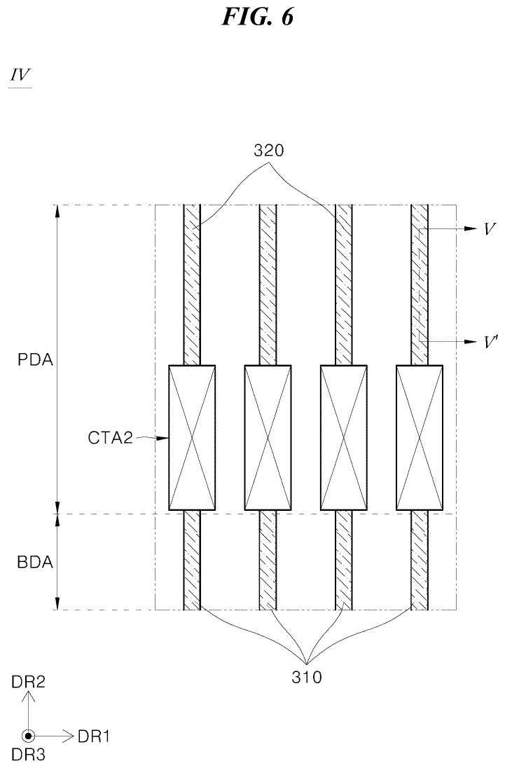

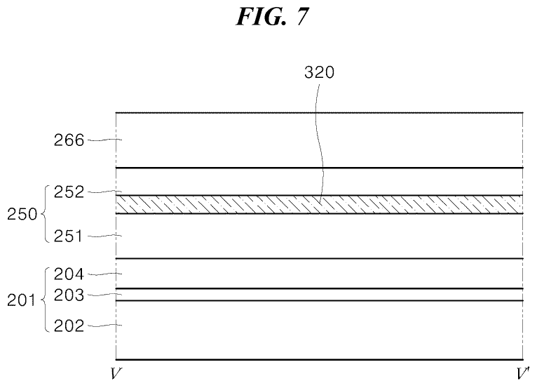

FIG. 6 is an enlarged view of an area IV of FIG. 2. FIG. 7 is a cross-sectional view taken along a line V-V′ of FIG. 6. FIG. 6 is a diagram illustrating a partial area of the bendable area BDA and a partial area of the pad area PDA of the display panel 200. In FIGS. 6 and 7, the same or similar elements or components as those described in FIGS. 4 and 5 may employ the same reference numerals.

As illustrated in to FIGS. 6 and 7, the connection line 310 extending from the bendable area BDA may be electrically connected to each of the plurality of signal lines 320 on the pad area PDA via a second contact area CTA2. For example, the signal line 320 may be high and lower potential power lines VDD and VSS. The signal line 320 may be electrically connected to the data driver DIC (see FIG. 2) disposed on the pad area PDA.

The second contact area CTA2 may have a structure corresponding to and similar to the structure of the first contact area CTA1 of FIGS. 4 and 5. As such, the plurality of connection lines 310 may be respectively connected to respective ones of the plurality of signal lines 320 in the second contact area CTA2 located in the pad area PDA. Thus, the second contact area CTA includes a second upper pattern over the pad area PDA with the plurality of lower patterns 330 below and spaced apart from the second upper pattern, and a plurality of second contact electrodes connecting respective ones of the plurality of second lower patterns 330 with the first upper pattern.

The plurality of connection lines 310 may extend in the second direction DR2 and may extend along the bendable area BDA and toward the pad area PDA. The signal line 320 may extend in the second direction DR2 and in the pad area PDA.

For example, the signal line 320 may be made of the same material as that of and may be disposed in the same layer as that of the connection line 310. In an example, the signal line 320 may have a multi-layered structure of titanium layer/aluminum layer/titanium layer (Ti/Al/Ti). The signal line 320 may be disposed on the second planarization layer 251.

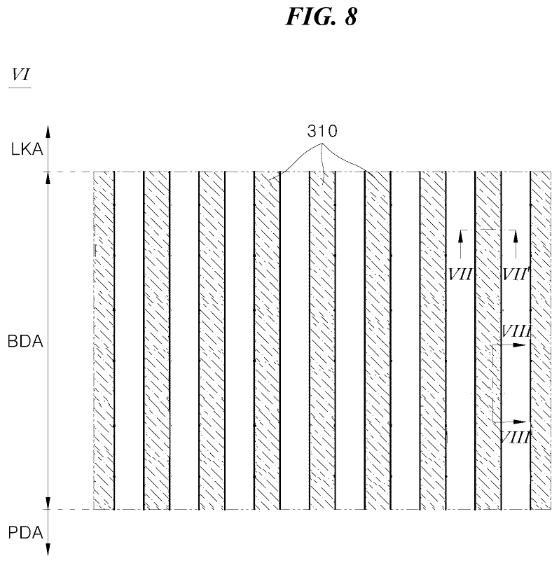

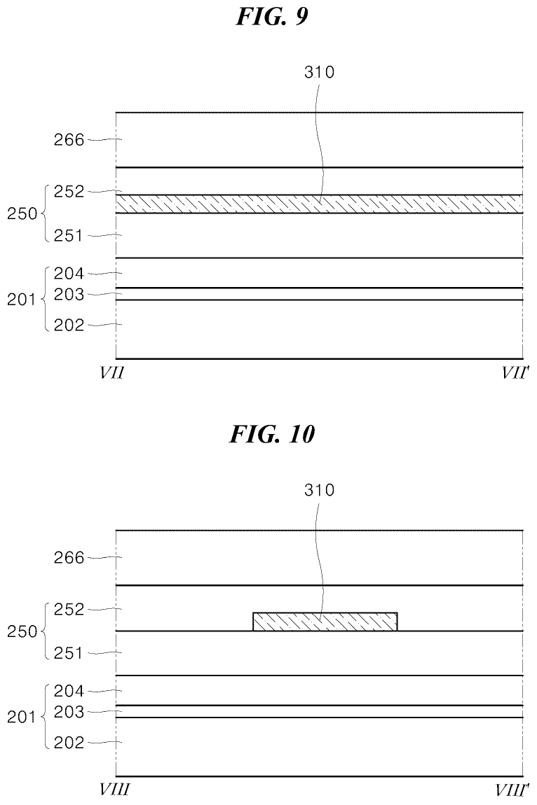

FIGS. 8 to 10 are diagrams illustrating a bendable area BDA according to an embodiment of the disclosure. FIG. 8 is an enlarged view of an area VI of FIG. 2. FIG. 9 is a cross-sectional view taken along a line VII-VII′ of FIG. 8. FIG. 10 is a cross-sectional view taken along a line VIII-VIII′ of FIG. 8. In FIGS. 8 to 10, the same components as the components described in FIGS. 3 and 5 may employ the same reference numerals.

With reference to FIGS. 8 to 10, the plurality of connection lines 310 extending from the link area LKA may be disposed on the bendable area BDA. The plurality of connection lines 310 may extend in the second direction DR2 and extend along the bendable area BDA and toward the pad area PDA. The plurality of connection lines 310 may be disposed between the first planarization layer 251 and the second planarization layer 252 in the cross-sectional view. For example, the plurality of connection lines 310 may be disposed on the first planarization layer 251 in the cross-sectional view. The connection line 310 may extend in one continuous line shape.

The connection line 310 disposed on the bendable area BDA may be subjected to stress due to a bending operation to increase strain. As the strain increases, defects, such as cracks in or damage to the planarization layer 250 including an organic insulating material, may occur.

When the moisture penetrates through the area in which the cracks or damage occurs, corrosion may occur in the connection line 310. This may lead to a defect in which the pixel PX does not operate in the display area, and thus product reliability of the display device may be deteriorated.

Accordingly, in another embodiment of the present disclosure, a structure that is rigid to strain stress and may prevent, or at least reduce, cracks in or damage to the connection line from occurring will be described.

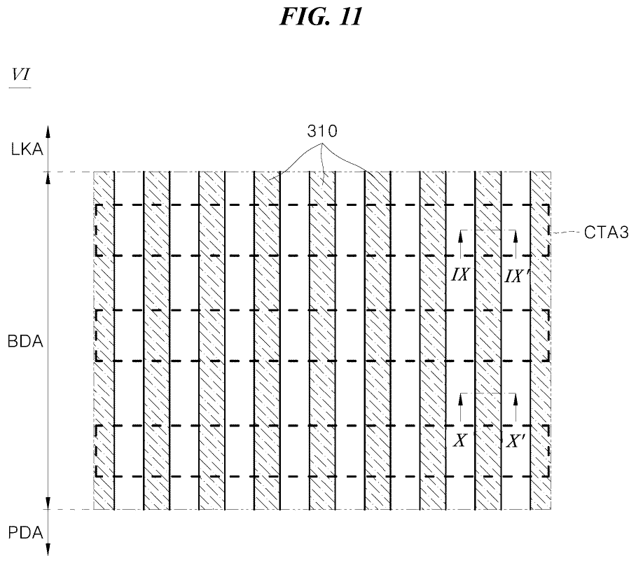

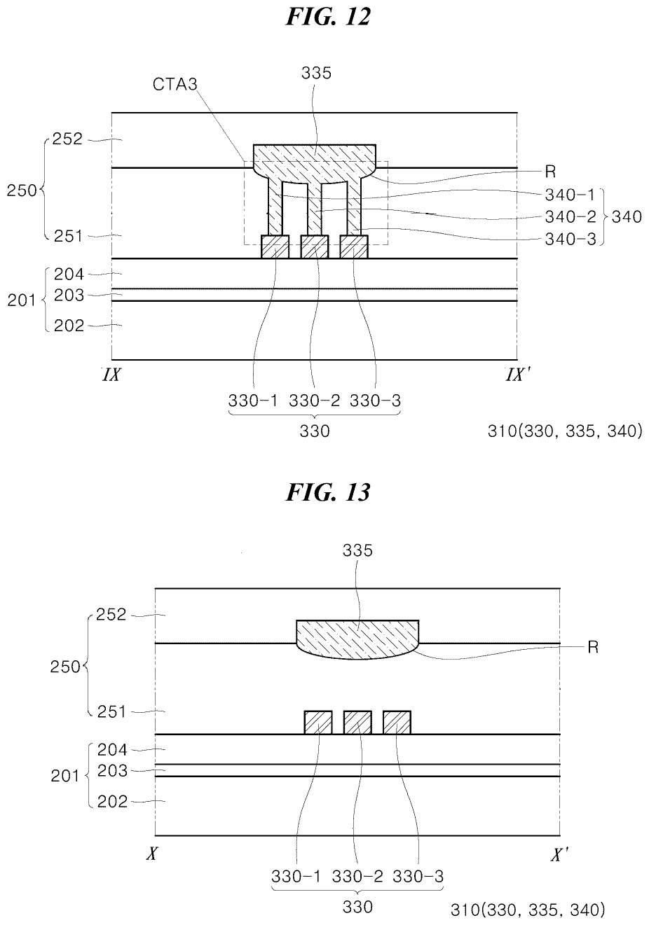

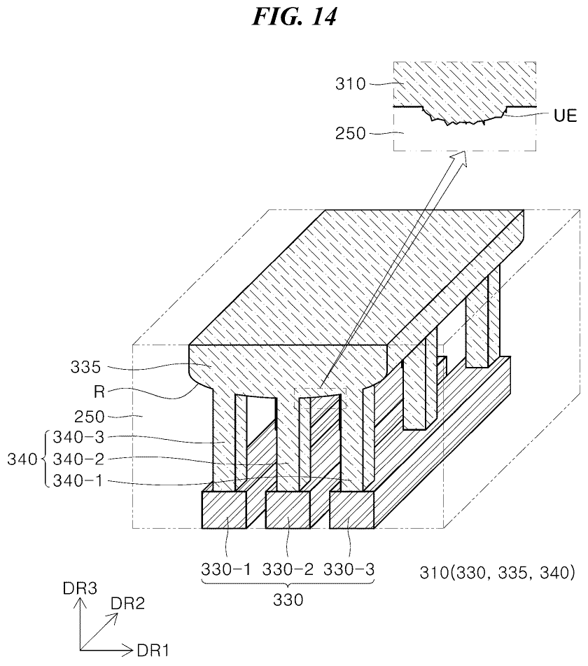

FIGS. 11 to 15 are diagrams illustrating a bendable area according to another embodiment of the present disclosure. FIG. 11 is an enlarged plan view of an area VI of FIG. 2. FIG. 12 is a cross-sectional view taken along a line IX-IX′ of FIG. 11. FIG. 13 is a cross-sectional view taken along a line X-X′ of FIG. 11. In FIGS. 11 to 15, the same components as the components described in FIGS. 3 to 5 may employ the same reference numerals.

As shown in FIGS. 11 to 15, the plurality of connection lines 310 extending from the link area LKA may be disposed on the bendable area BDA. The plurality of connection lines 310 may extend in the second direction DR2 and may extend on and along the bendable area BDA and toward the pad area PDA. The plurality of connection lines 310 may include high and lower potential power lines VDD and VSS.

Each of the plurality of connection lines 310 may include a plurality of lower patterns 330, an upper pattern 335 disposed to be vertically spaced apart from the plurality of lower patterns 330, and a plurality of contact electrodes 340 disposed between the upper pattern 335 and the lower patterns 330. The plurality of connection lines 310 may include a third contact area CTA3. The third contact area CTA3 may be an area in which the upper pattern 335 and the lower patterns 330 are connected to each other via the plurality of contact electrodes 340. As shown in FIG. 13, in the area where the third contact area CTA3 is not disposed, the upper pattern 335 and the lower patterns 330 may be disposed to be spaced apart from each other in the vertical direction while the upper pattern 335 and the lower patterns 330 are not electrically connected to each other.

The plurality of lower patterns 330 may be disposed on the second base layer 204 of the substrate 201 in the cross-sectional view. The plurality of lower patterns 330 may be made of the same material as that of and be formed in the same process as that of the second source electrode 245 and the second drain electrode 246. The plurality of lower patterns 330 may include patterns 330-1, 330-2, and 330-4 spaced apart from each other in the horizontal manner. For example, the plurality of lower patterns 330 may include a first lower pattern 330-1, a second lower pattern 330-2, and a third lower pattern 330-3. The first lower pattern 330-1, the second lower pattern 330-2, and the third lower pattern 330-3 may be disposed to be spaced apart from each other in the horizontal direction by an uniform spacing. However, embodiments of the present disclosure are not limited thereto. The first lower pattern 330-1, the second lower pattern 330-2, and the third lower pattern 330-3 may be separate line patterns not connected to each other, respectively.

The upper pattern 335 may have a single plate shape in the plan view. The upper pattern 335 may be connected to each of the first lower pattern 330-1, the second lower pattern 330-2, and the third lower pattern 330-3 via each of the plurality of contact electrodes 340. For example, the plurality of contact electrodes 340 may include a first contact electrode 340-1, a second contact electrode 340-2, and a third contact electrode 340-3. The first contact electrode 340-1, the second contact electrode 340-2, and the third contact electrode 340-3 may extend from a bottom surface of the upper pattern 335 through a partial thickness of the first planarization layer 252 so as be respectively connected to the first lower pattern 330-1, the second lower pattern 330-2, and the third lower pattern 330-3. In an example, one surface of the first contact electrode 340-1 may be in direct contact with an upper surface of the first lower pattern 330-1, one surface of the second contact electrode 340-2 may be in direct contact with an upper surface of the second lower pattern 330-2, and one surface of the third contact electrode 340-3 may be in direct contact with an upper surface of the third lower pattern 330-3. The first contact electrode 340-1, the second contact electrode 340-2, and the third contact electrode 340-3 may be integrally formed with the upper pattern 335.

The first planarization layer 251 may include a recess R depressed from an upper surface thereof toward the substrate 201. For example, the recess R may be gradually concave toward the second contact electrode 340-2 and may be defined between the upper pattern 335 and the first planarization layer 251. Accordingly, the first planarization layer 251 may have a curved shape in which the thickness thereof is smallest in an area in which the second contact electrode 340-2 is disposed and the thickness thereof increases as the first planarization layer 251 extends toward each of the first contact electrode 340-1 and the third contact electrode 340-3.

A lower surface of the recess R may have an increased surface roughness to form an unevenness or convex-concave portion UE. The upper pattern 335 may fill the recess R to extend along the convex-concave surface of the unevenness portion UE of the recess R. Accordingly, the contact area between the upper pattern 335 and the first planarization layer 251 may increase, thereby increasing the adhesive force therebetween.

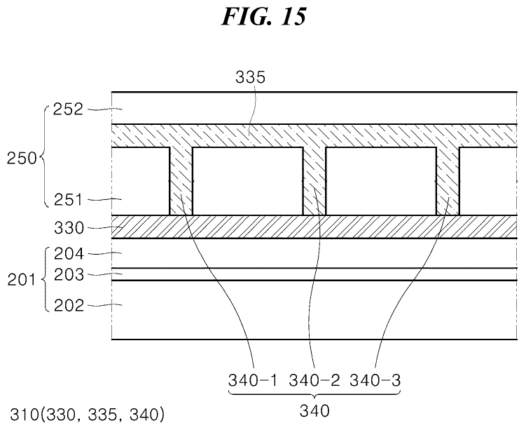

In accordance with FIG. 15, each of the first contact electrode 340-1, the second contact electrode 340-2, and the third contact electrode 340-3 may extend from the bottom surface of the upper pattern 335 extending in the same layer and in a continuous manner and then through the planarization layer 250 to be in direct contact with and connected to each of the plurality of lower patterns 330. Accordingly, even when a crack occurs in the upper pattern 335, the lower pattern 330 may be connected to one or more of the first contact electrode 340-1, the second contact electrode 340-2, or the third contact electrode 340-3, thereby maintaining the current flow path.

According to an embodiment of the disclosure, a magnitude of a tensile stress of the line may be reduced by dividing the connection line 310 disposed on the bendable area BDA into the upper pattern 335 and the plurality of lower patterns 330. Hereinafter, this will be described with reference to the drawings.

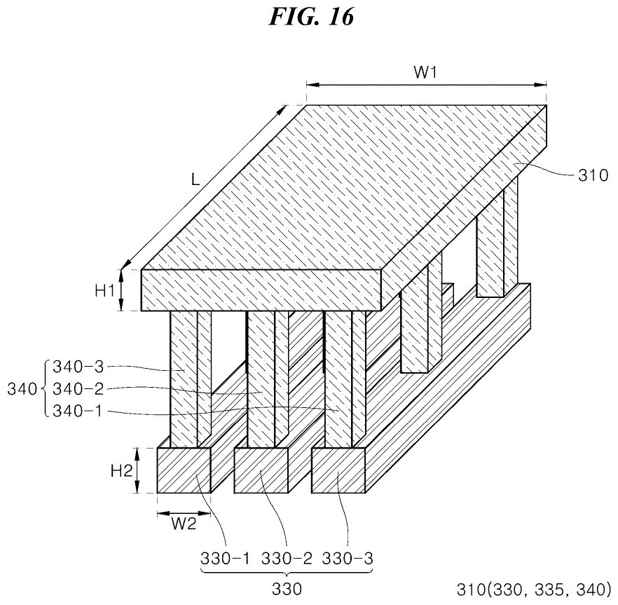

FIG. 16 is a diagram illustrating a connection line according to an embodiment of the present disclosure.

When the connection line 310 is formed as only a single layer of the upper pattern 335, strain stress may be concentrated on the upper pattern 335 during the bending operation, and thus, the cracks may occur in the upper pattern 335. For this reason, in an embodiment of the present disclosure, the lower pattern 330 may be added such that the connection line 310 may be composed of the upper pattern 335 and the lower pattern 330. Thus, a size of an area subjected to the bending stress generated during the bending operation may be increased to spread the strain stress.

For example, the upper pattern 335 may have a width W1, a length L, and a height H1. A cross-sectional area A1 of the upper pattern may amount to W1×H1. Each of the plurality of lower patterns 330 may have a length L, a width W2 and a height H2. Thus, a total cross-sectional area A2 of the plurality of lower patterns 330 may amount to W2×H2×the number of the plurality of lower patterns 330. Accordingly, a total cross-sectional area A of the connection line 310 according to an embodiment of the present disclosure may amount to a sum of the cross-sectional area A1 of the upper pattern 313 and the total cross-sectional area A2 of the plurality of lower patterns 330.

The strain stress σ applied across the cross-sectional area the connection line 310 may amount to a force (F)/a cross-sectional area (A) (σ=N/m²). In this regard, the strain stress may include both shear stress and strain stress applied to the cross-sectional area.

Accordingly, when the connection line 310 is composed of only a single layer of the upper pattern 335, the force F is intensively applied only to the cross-sectional area A1 of the upper pattern 335, the strain stress of the upper pattern 335 may increase, thereby causing cracks. However, according to an embodiment of the disclosure, because the strain stress σ applied across the cross-sectional area of the connection line 310 amounts to F/(A1+A2) (A1 is the cross-sectional area of the upper pattern 313, and A2 is the cross-sectional area of the plurality of lower patterns 330), the area subjected to the bending stress generated during the bending operation may be increased to the total cross-sectional area of the upper pattern 313 and the lower pattern 330. Accordingly, the area to which the strain stress is applied is increased, thereby preventing or reducing an increase in the strain stress, and thereby preventing or reducing cracks from occurring. This may prevent (or avoid) the connection line 310 from being damaged due to the moisture penetrating into the portion where the crack is generated.

In addition, in an embodiment of the present disclosure, an area in which the connection line 310 and the planarization layer 250 contact each other is increased, thereby further reducing the stress. In addition, in the embodiment of the present disclosure, the plurality of contact electrodes 340 provides multiple alternative current paths, which may prevent (or reduce) a decrease in resistance even when a crack occurs in either the upper pattern 335 or the lower pattern 330.

In one example, the number of the plurality of contact electrodes 340 electrically connecting the plurality of lower patterns 330 and the upper patterns 355 to each other and the size of the contact electrodes may vary based on embodiments. Hereinafter, this will be described with reference to the drawings.

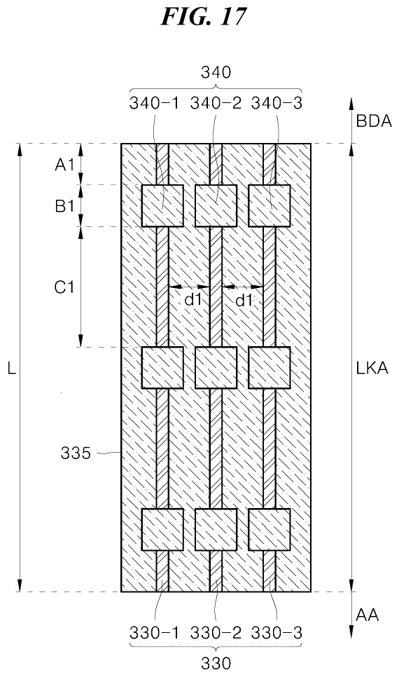

FIGS. 17 to 19 are respective diagrams illustrating connection lines according to still another embodiment of the present disclosure.

As shown in FIGS. 17 to 19, the plurality of lower patterns 330 may extend in the second direction DR2 of the substrate 201 and may extend in the bendable area BDA of the display panel or on the bendable area BDA of the substrate 201. The neighboring lower patterns 330 may be arranged to be spaced apart from each other by a first distance d in the first direction DR1 of the substrate 201. Each of the plurality of lower patterns 330 may have a first thickness. For example, the plurality of lower patterns 330 may include the first lower pattern 330-1, the second lower pattern 330-2, and the third lower pattern 330-3.

With reference to FIG. 17, each of the bendable area BDA, the link area LKA as a non-bendable area, and the pad area PDA as another non-bendable area may have a first spacing A1 from the outermost contact electrodes 340. For example, when the upper pattern 335 has the length L of 1073 micrometers (μm), the first spacing A1 may be 50 micrometers (μm), respectively.

Each of the plurality of contact electrodes 340 may be disposed between each lower pattern 330 and the single upper pattern 335. For example, a plurality of first contact electrodes 340-1 may be disposed on top of the first lower pattern 330-1 to be spaced apart therefrom. The first contact electrodes 340-1 may be arranged to be spaced apart from each other in the length direction of the upper pattern 335 by a second spacing C1. A width of one first contact electrode 340-1 may be a first size B1. For example, when the first size B1 of the first contact electrode 340-1 is 58.6 micrometers (μm), the second spacing C1 may be 400 micrometers (μm). In an example, three first contact electrodes 340-1 may be disposed on top of and vertically overlap the first lower pattern 330-1.

For example, a plurality of second contact electrodes 340-2 may be disposed on top of the second lower pattern 330-2 to be spaced apart therefrom. The second contact electrodes 340-2 may be arranged to be spaced apart from each other in the length direction of the upper pattern 335 by a second spacing C1. A width of one second contact electrode 340-2 may be a first size B1. For example, when the first size B1 of the second contact electrode 340-2 is 58.6 micrometers (μm), the second spacing C1 may be 400 micrometers (μm). In an example, three second contact electrodes 340-2 may be disposed on top of and vertically overlap the second lower pattern 330-2.

For example, a plurality of third contact electrodes 340-3 may be disposed on top of the third lower pattern 330-3 to be spaced apart therefrom. The third contact electrodes 340-3 may be arranged to be spaced apart from each other in the length direction of the upper pattern 335 by a second spacing C1. A width of one third contact electrode 340-3 may be a first size B1. For example, when the first size B1 of the third contact electrode 340-3 is 58.6 micrometers (μm), the second spacing C1 may be 400 micrometers (μm). In an example, three third contact electrodes 340-3 may be disposed on top of and vertically overlap the third lower pattern 330-3.

Accordingly, as illustrated in FIG. 17, according to another embodiment of the disclosure, a total of 9 contact electrodes 340 may be disposed to connect the single upper connection pattern 310 and the plurality of lower patterns 330 to each other.

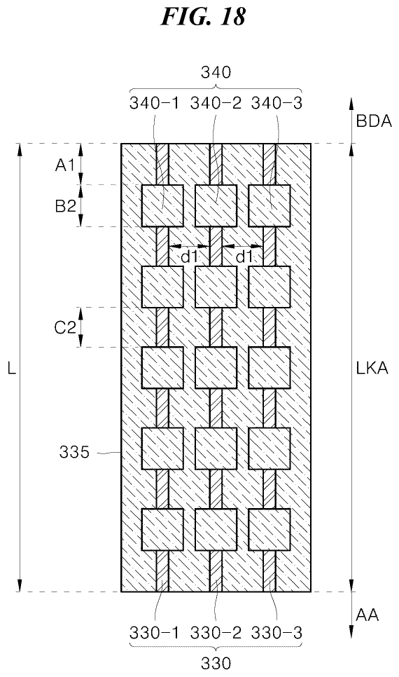

With reference to FIG. 18, a spacing between each of the contact electrodes 340 disposed at the outermost side of the link area LKA as a non-bendable area and the bendable area BDA may be a first spacing A1. For example, when the upper pattern 335 has the length L of 1073 micrometers (μm), the first spacing A1 may be 50 micrometers (μm).

Each of the plurality of contact electrodes 340 may be disposed between each lower pattern 330 and the single upper pattern 335. For example, a plurality of first contact electrodes 340-1 may be disposed on top of the first lower pattern 330-1 to be spaced apart therefrom. The first contact electrodes 340-1 may be arranged to be spaced apart from each other in the length direction of the upper pattern 335 by a third spacing C2. The third spacing C2 may be smaller than the second spacing C1 (see FIG. 17). The size of one first contact electrode 340-1 may be a second size B2 smaller than the first size B1 (see FIG. 17). For example, when the second size B2 of the first contact electrode 340-1 is 58.6 micrometers (μm), the third spacing C2 may be 170 micrometers (μm). In an example, five first contact electrodes 340-1 may be disposed on top of and vertically overlap the first lower pattern 330-1.

For example, a plurality of second contact electrodes 340-2 may be disposed on top of the second lower pattern 330-2 to be spaced apart therefrom. The second contact electrodes 340-2 may be arranged to be spaced apart from each other in the length direction of the upper pattern 335 by a third spacing C2. The third spacing C2 may be smaller than the second spacing C1 (see FIG. 17). The size of one second contact electrode 340-2 may be a second size B2 smaller than the second size B1 (see FIG. 17). For example, when the second size B2 of the second contact electrode 340-2 is 58.6 micrometers (μm), the third spacing C2 may be 170 micrometers (μm). In an example, five second contact electrodes 340-2 may be disposed on top of and vertically overlap the second lower pattern 330-2.

For example, a plurality of third contact electrodes 340-3 may be disposed on top of the third lower pattern 330-3 to be spaced apart therefrom. The third contact electrodes 340-3 may be arranged to be spaced apart from each other in the length direction of the upper pattern 335 by a third spacing C2. The third spacing C2 may be smaller than the second spacing C1 (see FIG. 17). The size of one third contact electrode 340-3 may be a second size B2 smaller than the second size B1 (see FIG. 17). For example, when the second size B2 of the third contact electrode 340-3 is 58.6 micrometers (μm), the third spacing C2 may be 170 micrometers (μm). In an example, five third contact electrodes 340-3 may be disposed on top of and vertically overlap the third lower pattern 330-3.

Accordingly, as illustrated in FIG. 18, according to still another embodiment of the disclosure, a total of 15 contact electrodes 340 may be disposed to connect the single upper connection pattern 310 and the plurality of lower patterns 330 to each other.

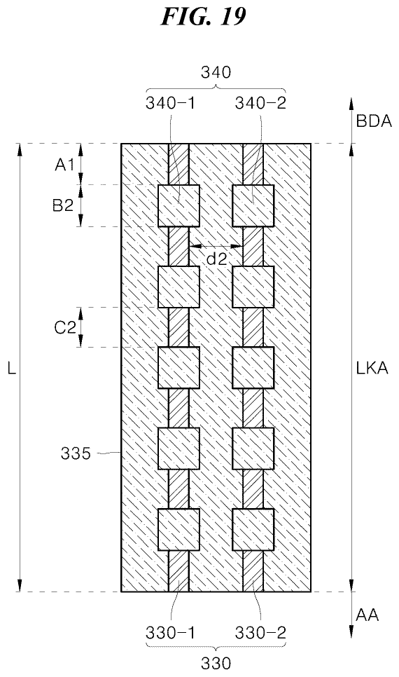

As shown in the example of FIG. 19, ten contact electrodes 340 may be disposed to connect one upper pattern 335 to the plurality of lower patterns 330. For example, the plurality of lower patterns 330 may include two patterns, for example, the first lower pattern 330-1 and the second lower pattern 330-2. In this case, a second width of each of the first lower pattern 330-1 and the second lower pattern 330-2 may be relatively larger than the first width of each of the three patterns, for example, the first lower pattern 330-1, the second lower pattern 330-2, and the third lower pattern 330-3 as described above with reference to FIG. 17 and FIG. 18. For example, when the first width is 2.8 micrometers (μm), the second width may be 4 micrometers (μm). In addition, a second distance d2 between the first lower pattern 330-1 and the second lower pattern 330-2 in FIG. 19 may be relatively greater than the first distance d1 (see FIG. 17 and FIG. 18) between adjacent ones of the three patterns, for example, the first lower pattern 330-1, the second lower pattern 330-2, and the third lower pattern 330-3 as described above with reference to FIG. 17 and FIG. 18.

According to still another embodiment of the disclosure in which ten contact electrodes 340 are disposed, the first spacing A1, the second spacing C2, and the second size B2 may be equal to those in the case in which the three patterns, for example, the first lower pattern 330-1, the second lower pattern 330-2, and the third lower pattern 330-3 are disposed, except for the width of each of the lower patterns 330.

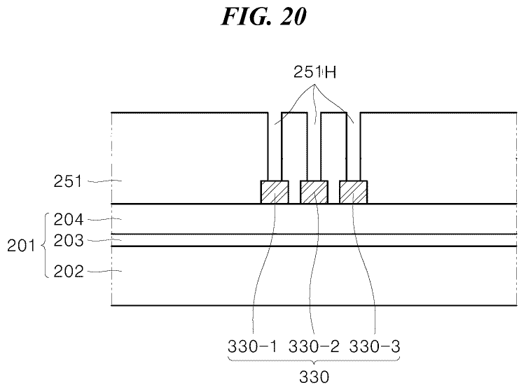

FIGS. 20 to 24 are diagrams illustrating a method for manufacturing a connection line according to an embodiment of the present disclosure.

As shown in FIG. 20, the plurality of lower patterns 330 may be formed on the substrate 201 and in the bendable area BDA. The substrate 201 may be a flexible plastic substrate. The substrate 201 may include the first base layer 202 and the second base layer 204 spaced apart from each other in the vertical direction, and the support layer 203 disposed therebetween. Each of the first base layer 202 and the second base layer 204 may include plastic of a flexible material. For example, each of the first base layer 202 and the second base layer 204 may include polyimide (PI). The support layer 203 may be made of a material having a relatively higher rigidity than that of each of the first base layer 202 and the second base layer 204 to reinforce the rigidity of the substrate 201.

The plurality of lower patterns 330 may be disposed on the second base layer 204 of the substrate 201. The plurality of lower patterns 330 may be made of the same material as that of and be formed in the same process as that of the second source electrode 245 and the second drain electrode 246. The plurality of lower patterns 330 may include the first lower pattern 330-1, the second lower pattern 330-2, and the third lower pattern 330-3. The first lower pattern 330-1, the second lower pattern 330-2, and the third lower pattern 330-3 may be disposed to be spaced apart from each other by an equal spacing in the horizontal direction. However, embodiments of the present disclosure are not limited thereto.

The first planarization layer 251 may be disposed on the plurality of lower patterns 330. The first planarization layer 251 may have a plurality of contact holes 251H defined therein respectively exposing portions of upper surfaces of the lower patterns 330. The plurality of contact holes 251H may be formed by partially etching the first planarization layer 251.

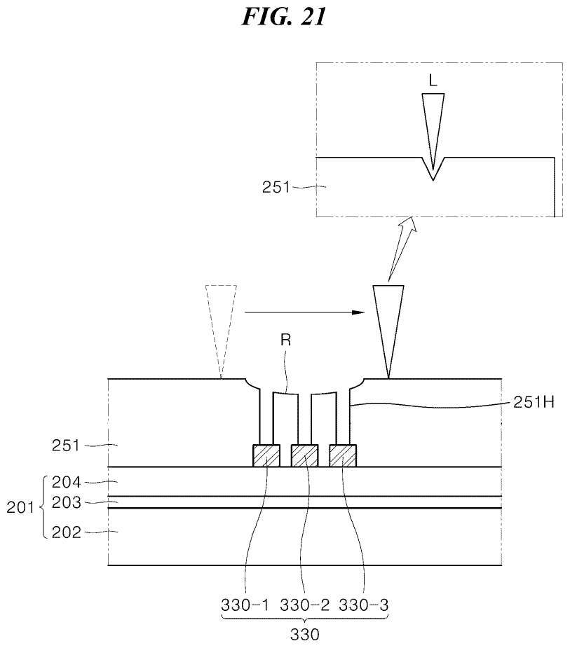

With reference to FIG. 21, laser L may be irradiated onto the first planarization layer 251 to form the recess R depressed downwardly by a predetermined depth from the upper surface of the first planarization layer 251. The laser L may be irradiated thereto while a laser source irradiating the laser moves from a position vertically overlapping the first lower pattern 330-1 to a position vertically overlapping the third lower pattern 330-3. The first planarization layer 251 may include an organic insulating material. When the laser L is irradiated onto the organic insulating material, the chemical bond in the organic insulating material may be weakened or broken due to the photochemical effect. In this process, a surface roughness of the first planarization layer 252 may increase, and thus irregularities or unevenness or convex-concave surface may be formed in the surface of the planarization layer 252. For example, the surface of the first planarization layer 252 defining the recess R irradiated with the laser L may have a surface roughness greater than that of a remaining surface of the first planarization layer 251 not subjected to the laser irradiation.

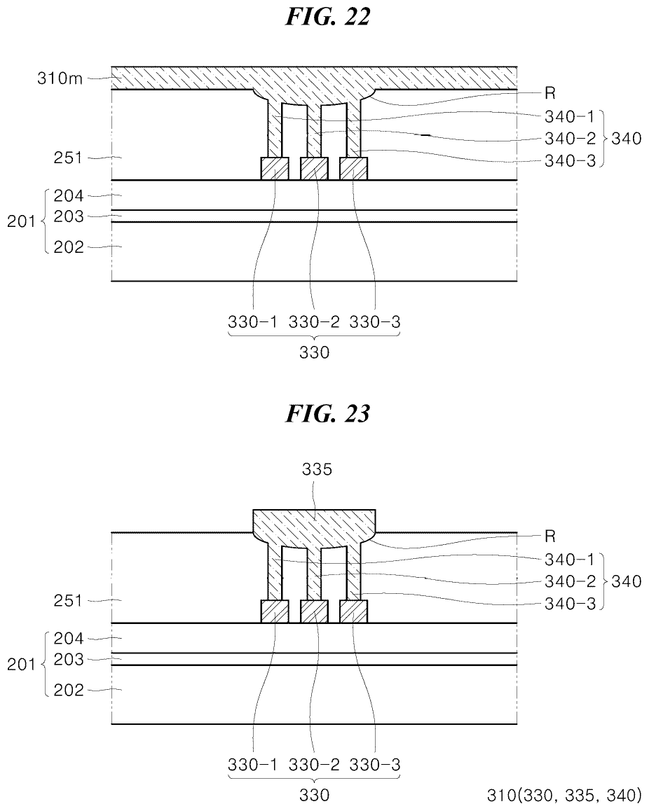

As illustrated in FIG. 22, an upper pattern material layer 310m to constitute the upper pattern may be formed on the upper surface of the first planarization layer 251 and in the recess R. The upper pattern material layer 310m may be made of the same material as that of and be formed in the same process as that of the pixel contact electrode 255 of the display area AA. In an example, the upper pattern material layer 310m may have a multilayer structure of titanium layer/aluminum layer/titanium layer (Ti/Al/Ti). The upper pattern material layer 310m may fill the contact holes 251H (see FIG. 21) and extends along and on the upper surface of the first planarization layer 251.

In the example of FIG. 23, a portion of the upper pattern material layer 310m in the remaining area except for an area of the upper pattern 335 to be formed has been removed. Accordingly, the connection line 310 may be formed in which the plurality of lower patterns 300 and the single upper pattern 335 are connected to each other via the plurality of contact electrodes 340. The plurality of contact electrodes 340 may include the first contact electrode 340-1, the second contact electrode 340-2, and the third contact electrode 340-3. For example, a lower end of the first contact electrode 340-1 may contact the first lower pattern 330-1, while an upper end thereof may contact the upper pattern 335. A lower end of the second contact electrode 340-2 may contact the second lower pattern 330-2, while an upper end thereof may contact the upper pattern 335. A lower end of the third contact electrode 340-3 may contact the third lower pattern 330-3, while an upper end thereof may contact the upper pattern 335.

Each of the first contact electrode 340-1, the second contact electrode 340-2, and the third contact electrode 340-3 may include a plurality of contact electrodes. For example, the first contact electrode 340-1 may include at least two or more first contact electrodes arranged and spaced apart from each other in the length direction in the plan view of the first lower pattern 330-1, the second contact electrode 340-2 may include at least two or more second contact electrodes arranged and spaced apart from each other in the length direction in the plan view of the second lower pattern 330-2, and the third contact electrode 340-3 may include at least two or more third contact electrodes arranged and spaced apart from each other in the length direction in the plan view of the third lower pattern 330-3.

The upper pattern 335 and the plurality of contact electrodes 340 may be integrally formed with each other. In an example, the upper surface of the upper pattern 335 may have a shape protruding by a predetermined thickness upwardly beyond the upper surface of the first planarization layer 25. A vertical level of a bottom surface of the recess R filled with the upper pattern 335 may be lower than a vertical level of the upper surface of the first planarization layer 251.

A surface area of the first planarization layer 251 defining the recess R may increase as the surface roughness of the bottom surface of the recess R increases due to the generation of the irregularities defined in the bottom surface of the recess R. Accordingly, the contact area between the first planarization layer 251 and the upper pattern 335 of the connection line 310 in the recess R increases, the adhesion therebetween may increase.

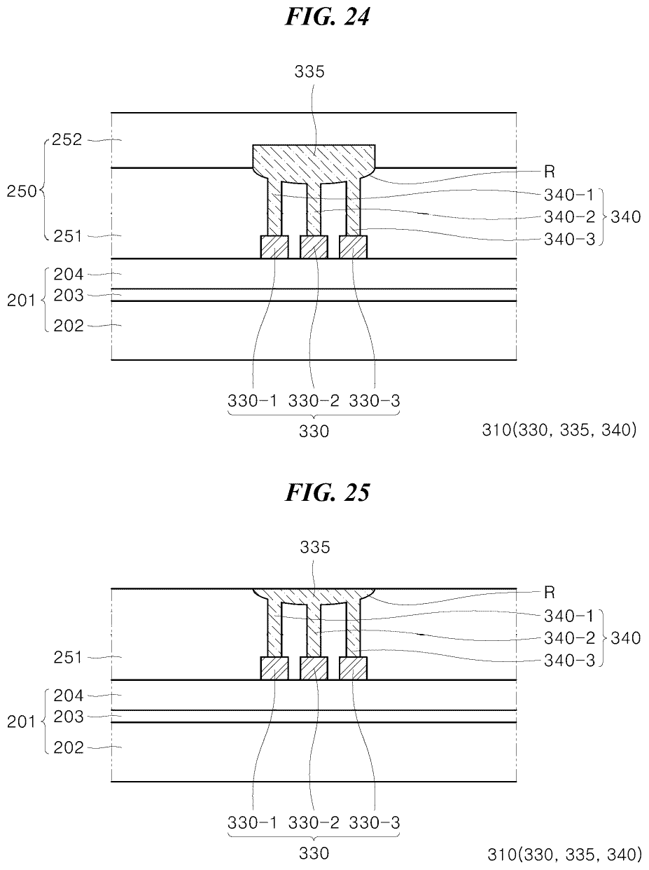

With reference to FIG. 24, the second planarization layer 252 may be formed on the upper pattern 335 and the first planarization layer 251. The second planarization layer 252 may include an organic insulating material. Thereafter, although not shown in the drawings, a barrier layer may be formed on the second planarization layer 252. The barrier layer may include the same material as that of each of the bank and the spacer.

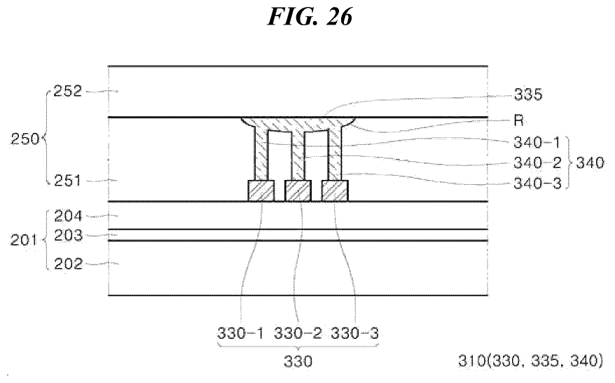

FIGS. 25 and 26 are diagrams illustrating a method for manufacturing a connection line according to still another embodiment of the present disclosure.

A process of forming the plurality of lower patterns 330 on the substrate 201, forming the contact holes 251H exposing respectively the portions of the upper surfaces of the plurality of lower patterns 330 in the first planarization layer 251, and then filling the contact holes 250 with the upper pattern material layer 310m to constitute the upper pattern 355 may be performed in the same process as described above with reference to FIGS. 20 to 22.

As shown in FIG. 25, a dry etching process is performed on the upper pattern material layer 310m (see FIG. 22) formed on the first planarization layer 251. The dry etching process may be performed without using an etching mask. The upper pattern 355 formed in the dry etching process may be constructed such that the upper surface of the upper pattern 355 may be coplanar with the upper surface of the first planarization layer 251.

As illustrated in FIG. 26, the second planarization layer 252 may be formed on the upper pattern 310 and the first planarization layer 251. Thereafter, although not shown in the drawings, a barrier layer may be formed on the second planarization layer 252. The barrier layer may include the same material as that of each of the bank and the spacer.

A display device according to one aspect and various embodiments of the present disclosure may be described as follows.

One aspect of the present disclosure provides a display device comprising: a substrate including a display area and a non-display area outside the display area with a link area and a bendable area included in the non-display area; a plurality of signal link lines on the link area; and a plurality of connection lines respectively connected to the plurality of signal link lines and extending from the link area to the bendable area to be on the bendable area, wherein each of the connection lines includes: an upper pattern; a plurality of lower patterns vertically spaced apart from the upper pattern; and a plurality of contact electrodes between the plurality of lower patterns and the upper pattern to connect the upper pattern to the plurality of lower patterns.

In accordance with some embodiments, the upper pattern has a single plate shape.

In accordance with some embodiments, the plurality of lower patterns include at least two lower patterns.

In accordance with some embodiments, the at least two lower patterns extend in a line and are not connected to each other and are spaced from each other horizontally.

In accordance with some embodiments, the display device further comprises an insulating layer under the upper pattern of the connection lines and including an organic insulating material.

In accordance with some embodiments, the plurality of contact electrodes vertically and partially extend through the insulating layer, and an upper surface of the insulating layer is in contact with a lower surface of the upper pattern.

In accordance with some embodiments, the insulating layer has a recess defined therein to be depressed toward the substrate, the upper pattern fills the recess, and a portion of the upper surface of the insulating layer defining the recess is in contact with the lower surface of the upper pattern.

In accordance with some embodiments, a portion of the upper surface of the insulating layer has a convex-concave surface, and the lower surface of the upper pattern contacts the convex-concave surface of the insulating layer.

In accordance with some embodiments, an upper surface of the upper pattern protrudes upwardly beyond the upper surface of the insulating layer.

In accordance with some embodiments, an upper surface of the upper pattern is coplanar with an upper surface of the insulating layer.

In accordance with some embodiments, the plurality of lower patterns include a first lower pattern, a second lower pattern, and a third lower pattern spaced apart from each other in a horizontal direction; the plurality of contact electrodes includes a first contact electrode, a second contact electrode, and a third contact electrode; the first contact electrode, the second contact electrode, and the third contact electrode are integrated with the upper pattern; and the first contact electrode, the second contact electrode, and the third contact electrode contact the first lower pattern, the second lower pattern, and the third lower pattern, respectively.

In accordance with some embodiments, the first contact electrode includes at least two first contact electrodes arranged and spaced apart from each other in a length direction of the first lower pattern, the second contact electrode includes at least two second contact electrodes arranged and spaced apart from each other in a length direction of the second lower pattern, and the third contact electrode includes at least two third contact electrodes arranged and spaced apart from each other in a length direction of the third lower pattern.

Another aspect of the present disclosure provides a display device comprising: a substrate including a display area and a non-display area outside the display area, the non-display area including a link area, a pad area, and a bendable area between the link area and the pad area; a plurality of signal link lines on the link area; a plurality of signal lines on the pad area; and a plurality of connection lines respectively connected to the plurality of signal link lines in the link area and respectively connect to the plurality of signal lines in the pad area, the plurality of connection lines extending from the link area to the pad area via the bendable area, wherein each of the connection lines includes: a first upper pattern over the link area, a second upper pattern over the pad area, a plurality of lower patterns below and spaced apart from the first and second upper patterns, a plurality of first contact electrodes connecting respective ones of the plurality of the lower patterns with the first upper pattern, and a plurality of second contact electrodes connecting respective ones of the plurality of the lower patterns with the first upper pattern.

In accordance with some embodiments, each of the first and second upper patterns has a single plate shape.

In accordance with some embodiments the plurality of lower patterns include at least two lower patterns.

In accordance with some embodiments, the at least two lower patterns extend in a line and are not connected to each other over the bendable area.

In accordance with some embodiments, the at least two lower patterns are spaced from each other horizontally.

In accordance with some embodiments, the display device further comprises an organic insulating layer disposed under the first upper pattern.

In accordance with some embodiments, the plurality of first contact electrodes vertically and partially extend through the insulating layer, and an upper surface of the insulating layer is in contact with a lower surface of the first upper pattern.

In accordance with some embodiments, the plurality of lower patterns includes at least three lower patterns spaced apart from each other in a horizontal direction, the plurality of first contact electrodes includes at least three first contact electrodes each connected with the first upper pattern, and the at least three first contact electrodes are each connected with respective ones the at least three lower patterns on a one-to-one basis.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a display area and a non-display area, the non-display area being outside the display area, wherein a link area and a bendable area included in the non-display area;
a plurality of signal link lines on the link area; and
a plurality of connection lines respectively connected to the plurality of signal link lines and extending from the link area to the bendable area to be on the bendable area,
wherein each of the connection lines includes:
an upper pattern;
a plurality of lower patterns vertically spaced apart from the upper pattern; and
a plurality of contact electrodes between the plurality of lower patterns and the upper pattern to connect the upper pattern to the plurality of lower patterns.

2. The display device of claim 1, wherein the upper pattern has a single plate shape.

3. The display device of claim 1, wherein the plurality of lower patterns include at least two lower patterns.

4. The display device of claim 3, wherein the at least two lower patterns extend in a line and are not connected to each other and are spaced from each other horizontally.

5. The display device of claim 1, further comprising an insulating layer under the upper pattern of the connection lines and including an organic insulating material.

6. The display device of claim 5, wherein the plurality of contact electrodes vertically and partially extend through the insulating layer, and
wherein an upper surface of the insulating layer is in contact with a lower surface of the upper pattern.

7. The display device of claim 6, wherein the insulating layer has a recess defined therein to be depressed toward the substrate,
wherein the upper pattern fills the recess, and
wherein a portion of the upper surface of the insulating layer defining the recess is in contact with the lower surface of the upper pattern.

8. The display device of claim 6, wherein a portion of the upper surface of the insulating layer has a convex-concave surface, and
wherein the lower surface of the upper pattern contacts the convex-concave surface of the insulating layer.

9. The display device of claim 5, wherein an upper surface of the upper pattern protrudes upwardly beyond the upper surface of the insulating layer.

10. The display device of claim 5, wherein an upper surface of the upper pattern is coplanar with an upper surface of the insulating layer.

11. The display device of claim 1, wherein the plurality of lower patterns include a first lower pattern, a second lower pattern, and a third lower pattern spaced apart from each other in a horizontal direction,
wherein the plurality of contact electrodes includes a first contact electrode, a second contact electrode, and a third contact electrode,
wherein the first contact electrode, the second contact electrode, and the third contact electrode are integrated with the upper pattern, and
wherein the first contact electrode, the second contact electrode, and the third contact electrode contact the first lower pattern, the second lower pattern, and the third lower pattern, respectively.

12. The display device of claim 11, wherein the first contact electrode includes at least two first contact electrodes arranged and spaced apart from each other in a length direction of the first lower pattern,
wherein the second contact electrode includes at least two second contact electrodes arranged and spaced apart from each other in a length direction of the second lower pattern, and
wherein the third contact electrode includes at least two third contact electrodes arranged and spaced apart from each other in a length direction of the third lower pattern.

13. A display device, comprising:
a substrate including a display area and a non-display area outside the display area, the non-display area including a link area, a pad area, and a bendable area between the link area and the pad area;
a plurality of signal link lines on the link area;
a plurality of signal lines on the pad area; and
a plurality of connection lines respectively connected to the plurality of signal link lines in the link area and respectively connect to the plurality of signal lines in the pad area, the plurality of connection lines extending from the link area to the pad area via the bendable area,
wherein each of the connection lines includes:
a first upper pattern over the link area,
a second upper pattern over the pad area,
a plurality of lower patterns below and spaced apart from the first and second upper patterns,
a plurality of first contact electrodes connecting respective ones of the plurality of the lower patterns with the first upper pattern, and
a plurality of second contact electrodes connecting respective ones of the plurality of the lower patterns with the first upper pattern.

14. The display device of claim 13, wherein each of the first and second upper patterns has a single plate shape.

15. The display device of claim 13, wherein the plurality of lower patterns include at least two lower patterns.

16. The display device of claim 15, wherein the at least two lower patterns extend in a line and are not connected to each other over the bendable area.

17. The display device of claim 16, wherein the at least two lower patterns are spaced from each other horizontally.

18. The display device of claim 13, further comprising an organic insulating layer disposed under the first upper pattern.

19. The display device of claim 18, wherein the plurality of first contact electrodes vertically and partially extend through the insulating layer, and
wherein an upper surface of the insulating layer is in contact with a lower surface of the first upper pattern.

20. The display device of claim 13, wherein the plurality of lower patterns includes at least three lower patterns spaced apart from each other in a horizontal direction,
wherein the plurality of first contact electrodes includes at least three first contact electrodes each connected with the first upper pattern, and
wherein the at least three first contact electrodes are each connected with respective ones the at least three lower patterns on a one-to-one basis.
